(19) United States
(12) Patent Application Publication
(10) Pub. No.: US 2010/0241376 A1
(43) Pub. Date: Sep. 23, 2010

(54) CONTROL APPARATUS AND CONTROL METHOD FOR SECONDARY BATTERY

(75) Inventors: Yoshiaki Kikuchi, Toyota-shi (JP); Teruo Ishishita, Miyoshi-shi (JP); Yuji Nishi, Nagoya-shi (JP); Daisuke Kuroda, Chiryu-shi (JP)

Correspondence Address: OLIFF & BERRIDGE, PLC, P.O. BOX 320850, ALEXANDRIA, VA, 22320-4850, US

(73) Assignees: Toyota Jidosha Kabushiki Kaisha, Toyota-shi, Aichi-ken (JP); Denso Corporation, Kariya-shi, Aichi-ken (JP)

(21) Appl. No.: 12/741,933

(22) PCT Filed: Sep. 17, 2008
(86) PCT No.: PCT/JP2008/066727

§ 371 Date: May 7, 2010

(30) Foreign Application Priority Data
Nov. 13, 2007 (JP) 2007-294552

(51) Int. Cl. G01R 31/36

(52) U.S. Cl. 702/63

(57) ABSTRACT

An ECU calculates an evaluation value decrease amount D(−) in response to a reduction of unevenness of lithium ion concentration caused by diffusion of lithium ions resulting from a lapse of one cycle time ΔT, calculates an evaluation value increase amount D(+) in response to an increase of the unevenness of the lithium ion concentration caused by discharging during a lapse of one cycle time ΔT, and calculates a present value D(N) of a battery deterioration evaluation value D due to high-rate discharging, as a previous value D(N−1)−evaluation value decrease amount D(−)+evaluation value increase amount D(+). If battery deterioration evaluation value D exceeds a predetermined target value E, the ECU sets a discharging power limit value WOUT that is a limit value of electric power to be discharged from a battery, to a value lower than a maximum value W(MAX).

### TECHNICAL FIELD

The present invention relates to control of a secondary battery, and particularly, to control of a secondary battery mounted on a vehicle.

### BACKGROUND ART

Hybrid cars, fuel-cell cars, and electric cars traveling with a driving force from a motor are known. Such a vehicle is equipped with a battery (secondary battery) storing electric power to be supplied to the motor. The battery has a property that it is deteriorated by a load and its performance is impaired. A technique to suppress such deterioration and make full use of the performance of a power storage device is disclosed, for example, in Japanese Patent Laying-Open No. 2005-124353 (Patent Document 1).

A control apparatus disclosed in Japanese Patent Laying-Open No. 2005-124353 controls a power storage device mounted on a vehicle. The control apparatus includes: a limiting unit limiting charging power to the power storage device and discharging power from the power storage device; a detection unit detecting a value related to at least one of current values of the charging power to the power storage device and the discharging power from the power storage device, a temperature of the power storage device, and a rate of change in an acceleration pedal position; a storage unit storing a history related to the detected value; a determination unit determining a deterioration degree of the power storage device based on the stored history; and an adjustment unit adjusting limitation by the limiting unit based on the deterioration degree.

According to the control apparatus disclosed in Japanese Patent Laying-Open No. 2005-124353, a value related to at least one of current values of the charging power to the power storage device and the discharging power from the power storage device, a temperature of the power storage device, and a rate of change in an acceleration pedal position is detected by the detection unit, and a history thereof is stored in the storage unit. Thus, an operation state of the power storage device in a predetermined period can be stored. Further, a deterioration degree of the power storage device is determined based on the stored history, i.e., the operation state of the power storage device. Based on the deterioration degree thus determined, limitation by the limiting unit is adjusted by the adjustment unit. Here, for example, if the limitation is relaxed when the deterioration degree is lower than a predetermined deterioration degree, and tightened when the deterioration degree is higher than the predetermined deterioration degree, an increase in a load on the power storage device can be tolerated when the deterioration degree is lower, and the load on the power storage device can be suppressed when the deterioration degree is higher. As a result, a control apparatus for a power storage device capable of making full use of the performance of the power storage device in accordance with the deterioration degree based on the operation state of the power storage device can be provided.

### Patent Document 1: Japanese Patent Laying-Open No. 2005-124353

### DISCLOSURE OF THE INVENTION

### Problems to be Solved by the Invention

Now, when discharging with a relatively large current with respect to a battery capacity (hereinafter also referred to as discharging with a large current or high-rate discharging) is continuously performed, a phenomenon in which a battery voltage starts decreasing rapidly at certain timing may occur. If this phenomenon continues further, a battery may be deteriorated. However, since the determination unit in the control apparatus disclosed in Japanese Patent Laying-Open No. 2005-124353 is not intended to actively determine the deterioration degree due to high-rate discharging, it cannot properly recognize whether or not the battery is in a state where deterioration due to high-rate discharging may occur. Therefore, there may occur a case where discharging power is not limited even in a state where deterioration due to high-rate discharging may occur, and thus the battery is deteriorated, or a case where discharging power is limited even in a state where deterioration due to high-rate discharging is not likely to occur, and thus motive power performance of the vehicle is degraded.

The present invention has been made to solve the aforementioned problem, and one object of the present invention is to provide a control apparatus and a control method for a secondary battery capable of suppressing degradation of motive power performance of a vehicle and also suppressing deterioration of the secondary battery due to high-rate discharging.

### Means for Solving the Problems

A control apparatus in accordance with the present invention controls a secondary battery mounted on a vehicle. The control apparatus includes a detection unit detecting a charging current value to the secondary battery and a discharging current value from the secondary battery, and a control unit connected to the detection unit. The control unit stores a history of the current value detected by the detection unit, calculates an evaluation value related to deterioration of the secondary battery due to discharging with a large current based on the stored history, and controls a value of discharging power from the secondary battery based on the calculated evaluation value.

According to the present invention, a charging current value to the secondary battery and a discharging current value from the secondary battery are detected, and a history of the detected current value is stored. Accordingly, how long discharging with a large current has continued can be stored. Based on the history, an evaluation value related to deterioration of the secondary battery due to discharging with a large current is calculated. Therefore, for example when discharging with a large current is performed continuously, the evaluation value can be calculated to shift to a deterioration side, as compared with a case where discharging with a large current is performed intermittently or discharging with a small current is performed. Based on the evaluation value thus calculated, a value of discharging power is controlled. Thereby, for example when the evaluation value is on a non-deterioration side and lower than a predetermined target value, discharging with a large current can be tolerated without limiting the value of the discharging power, and degradation of motive power performance of the vehicle can be suppressed. On the other hand, when the evaluation value shifts to the deterioration side beyond the predetermined target value, deterioration due to discharging with a large current can be suppressed by limiting the value of the discharging power. As a result, a control apparatus for a secondary battery capable of suppressing degradation of motive power performance of a vehicle and also suppressing deterioration of the secondary battery due to discharging with a large current can be provided.

Preferably, the control unit calculates the evaluation value to correspond to a change in unevenness of ion concentration in an electrolyte in the secondary battery.

According to the present invention, due to discharging, ions in an electrolyte in the secondary battery move from one electrode to the other electrode, resulting in unevenness of ion concentration in the electrolyte. The unevenness is considered as one of the causes of deterioration due to discharging with a large current. Accordingly, the evaluation value is calculated to correspond to a change in the unevenness of the ion concentration in the electrolyte in the secondary battery. For example, when it is presumed that discharging with a large current continues and the unevenness of the ion concentration is increased, the evaluation value is calculated to shift to the deterioration side. On the other hand, when it is presumed that charging or discharging with a small current is performed and the unevenness of the ion concentration is reduced, the evaluation value is calculated to shift to the non-deterioration side. In this manner, a change in the unevenness of the ion concentration considered as a cause of deterioration due to discharging with a large current is reflected in the evaluation value. Therefore, how close the state of the secondary battery is to the state where deterioration due to discharging with a large current occurs can be properly recognized from the evaluation value. Based on the evaluation value thus calculated, a value of discharging power is controlled. Thereby, the discharging power can be limited at appropriate timing to achieve both suppression of deterioration due to discharging with a large current and motive power performance of the vehicle.

More preferably, the control unit calculates the evaluation value to shift to a deterioration side when it is presumed that the unevenness of the ion concentration is increased.

According to the present invention, when it is presumed that the unevenness of the ion concentration, which is considered as a cause of deterioration due to discharging with a large current, is increased, the evaluation value is calculated to shift to the deterioration side. Thereby, a situation that the state of the secondary battery is approaching the state where deterioration due to discharging with a large current occurs can be appropriately reflected in the evaluation value.

More preferably, the control unit calculates a shift amount of the evaluation value to a deterioration side in response to an increase of the unevenness of the ion concentration due to discharging, calculates a shift amount of the evaluation value to a non-deterioration side in response to a reduction of the unevenness of the ion concentration due to a lapse of time, and calculates the evaluation value based on the shift amount to the deterioration side and the shift amount to the non-deterioration side.

According to the present invention, due to discharging, the unevenness of the ion concentration in the electrolyte occurs, and the unevenness is reduced by diffusion of ions resulting from a lapse of time. Accordingly, a shift amount of the evaluation value to the deterioration side is calculated in response to an increase of the unevenness of the ion concentration due to discharging, and a shift amount of the evaluation value to the non-deterioration side is calculated in response to a reduction of the unevenness of the ion concentration due to a lapse of time. The evaluation value is calculated based on the shift amount to the deterioration side and the shift amount to the non-deterioration side. Therefore, the unevenness of the ion concentration can be appropriately reflected in the evaluation value.

More preferably, the control unit calculates a shift amount to the deterioration side at second timing at which a predetermined period has elapsed from first timing based on a current value detected at the second timing and the predetermined period, calculates a shift amount to the non-deterioration side at the second timing based on an evaluation value at the first timing and the predetermined period, and calculates an evaluation value at the second timing based on the evaluation value at the first timing, the shift amount to the deterioration side at the second timing, and the shift amount to the non-deterioration side at the second timing.

According to the present invention, a shift amount to the deterioration side at second timing at which a predetermined period has elapsed after first timing is calculated based on a current value detected at the second timing and the predetermined period. Therefore, the shift amount to the deterioration side at the second timing can be calculated on the assumption that the current value detected at the second timing is maintained for the predetermined period. On the other hand, a shift amount to the non-deterioration side at the second timing is calculated based on an evaluation value at the first timing and the predetermined period. Therefore, the shift amount to the non-deterioration side at the second timing can be calculated in response to a reduction of the unevenness of the ion concentration caused by diffusion of ions resulting from a lapse of the predetermined period. An evaluation value at the second timing is calculated based on the evaluation value at the first timing, the shift amount to the deterioration side at the second timing, and the shift amount to the non-deterioration side at the second timing. Therefore, the evaluation value can be calculated to approximate to the unevenness of the ion concentration simply and appropriately.

More preferably, when the evaluation value shifts to a deterioration side beyond a predetermined target value, the control unit decreases the value of the discharging power.

According to the present invention, when the evaluation value shifts to the deterioration side beyond a predetermined target value, the value of the discharging power is decreased. Therefore, when the evaluation value is on a non-deterioration side and lower than the predetermined target value, discharging with a large current can be tolerated without limiting the value of the discharging power, and degradation of motive power performance of the vehicle can be suppressed, and when the evaluation value shifts to the deterioration side beyond the predetermined target value, deterioration due to discharging with a large current can be suppressed by limiting the value of the discharging power.

More preferably, the control unit decreases the value of the discharging power in response to a difference between the evaluation value and the target value.

According to the present invention, the value of the discharging power is decreased in response to a difference between the evaluation value and the target value. Therefore, when there is a large difference between the evaluation value and the target value, the unevenness of the ion concentration can be further reduced by decreasing the value of the discharging power, as compared with a case where there is a small difference therebetween.

More preferably, the secondary battery is a lithium ion battery.

According to the present invention, deterioration of a lithium ion battery due to discharging with a large current can be suppressed.

### BRIEF DESCRIPTION OF THE DRAWINGS

FIG. 1 is a view showing a structure of a vehicle equipped with a control apparatus in accordance with an embodiment of the present invention (type 1).

FIG. 2 is a view showing a structure of a vehicle equipped with the control apparatus in accordance with the embodiment of the present invention (type 2).

FIG. 3 is a functional block diagram of the control apparatus in accordance with the embodiment of the present invention.

FIG. 4 is a flowchart showing a control structure of an ECU constituting the control apparatus in accordance with the embodiment of the present invention.

FIG. 5 is a view showing the relationship among a forgetting coefficient A, a battery temperature TB, and an SOC in accordance with the embodiment of the present invention.

FIG. 6 is a view showing the relationship among a limit threshold value C, battery temperature TB, and the SOC in accordance with the embodiment of the present invention.

FIG. 7 is a timing chart showing the relationship between a battery deterioration evaluation value D and discharging control in accordance with the embodiment of the present invention.

### DESCRIPTION OF THE REFERENCE SIGNS

100: engine, 200: generator, 300: PCU, 302: inverter, 304: converter, 400: battery, 500: motor, 600: ECU, 604: memory, 606: counter, 610: voltmeter, 612: ammeter, 614: battery temperature sensor, 620: calculation unit, 622: battery deterioration evaluation value storage unit, 624: battery deterioration evaluation value calculation unit, 626: discharging power control unit, 700: power split device, 800: reduction gear, 900: wheels, 1100: acceleration pedal position sensor.

### BEST MODES FOR CARRYING OUT THE INVENTION

Hereinafter, an embodiment of the present invention will be described with reference to the drawings. In the following description, identical parts will be designated by the same reference numerals. Since their names and functions are also the same, the detailed description thereof will not be repeated.

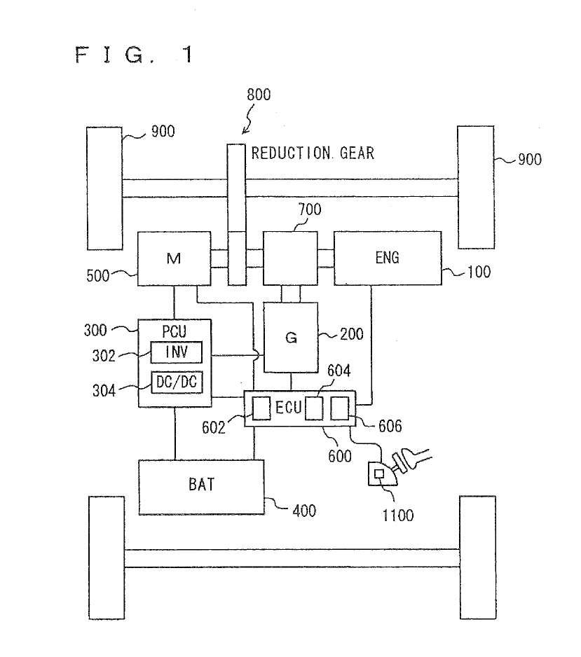

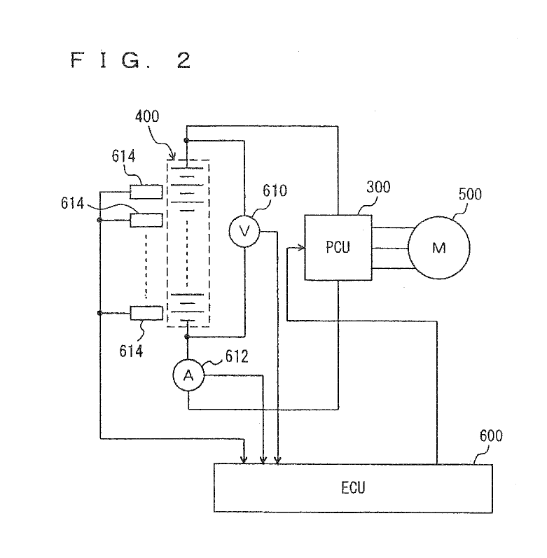

Referring to FIGS. 1 and 2, a hybrid vehicle equipped with a control apparatus in accordance with the present embodiment will be described.

The hybrid vehicle includes an engine 100, a generator 200, a PCU (Power Control Unit) 300, a battery 400, a motor 500, and an ECU (Electronic Control Unit) 600 connected to all of these components. The control apparatus in accordance with the embodiment of the present invention is implemented by a program executed by ECU 600. While the present embodiment is described using a hybrid vehicle equipped with engine 100, the present invention is not limited to a hybrid vehicle equipped with engine 100, and it is applicable to a hybrid vehicle equipped with a fuel cell in place of engine 100 (a fuel-cell car), an electric car equipped with only battery 400, or the like.

Motive power generated by engine 100 is split by a power split device 700 into two routes. One of them is a route to drive wheels 900 through a reduction gear 800. The other is a route to drive generator 200 for generating electric power.

While generator 200 generates electric power by the motive power of engine 100 split by power split device 700, the electric power generated by generator 200 is selectively used in accordance with a driving state of the vehicle, or an SOC (State Of Charge) of battery 400. For example, during normal traveling or during sudden acceleration, the electric power generated by generator 200 directly serves as electric power for driving motor 500. On the other hand, when the SOC of battery 400 is lower than a predetermined value, the electric power generated by generator 200 is converted from AC (Alternating Current) power to DC (Direct Current) power by an inverter 302 of PCU 300, and after voltage is adjusted by a converter 304, the electric power is stored in battery 400.

Battery 400 is an assembled battery in which a plurality of modules, each integrally formed of a plurality of lithium ion battery cells, are serially connected. A positive electrode of a lithium ion battery cell is made of a material capable of reversibly absorbing/emitting lithium ions (for example, a lithium-containing oxide), and emits lithium ions into an electrolyte in a charging process and absorbs lithium ions from the electrolyte emitted from a negative electrode in a discharging process. The negative electrode of the lithium ion battery cell is made of a material capable of reversibly absorbing/emitting lithium ions (for example, carbon), and absorbs lithium ions from the electrolyte emitted from the positive electrode in the charging process and emits lithium ions into the electrolyte in the discharging process.

Motor 500 is a three-phase AC motor, and driven by at least one of the electric power stored in battery 400 and the electric power generated by generator 200. A driving force of motor 500 is transmitted to wheels 900 via reduction gear 800. Thus, motor 500 assists engine 100 in allowing the vehicle to travel, or allows the vehicle to travel only by the driving force from motor 500.

On the other hand, during regenerative braking of the hybrid vehicle, motor 500 is driven by wheels 900 via reduction gear 800, and motor 500 is actuated as a generator. Thus, motor 500 serves as a regenerative brake that converts braking energy into electric power. The electric power generated by motor 500 is stored in battery 400 via inverter 302.

ECU 600 includes a CPU (Central Processing Unit) 602, a memory 604, and a counter 606. CPU 602 performs operation processing based on the driving state of the vehicle, an acceleration pedal position detected by an acceleration pedal position sensor 1100, a rate of change in the acceleration pedal position, a position of a shift lever, the SOC of battery 400, a map and a program stored in memory 604, and the like. Thus, ECU 600 controls equipment mounted on the vehicle so that the vehicle attains a desired driving state.

As shown in FIG. 2, a voltmeter 610 detecting a charging/discharging voltage value of battery 400, an ammeter 612 detecting a charging/discharging current value thereof, and a battery temperature sensor 614 detecting a battery temperature TB thereof are connected to ECU 600. ECU 600 calculates a charging/discharging power value of battery 400 based on the charging/discharging voltage value detected by voltmeter 610 and the charging/discharging current value detected by ammeter 612, and calculates the SOC of battery 400 by integrating the charging current values and the discharging current values. A history of the charging/discharging current value detected by ammeter 612 is stored in memory 604.

ECU 600 sets a charging power limit value that is a limit value of electric power to be charged to battery 400 (hereinafter, the “charging power limit value” will be expressed as WIN), and a discharging power limit value that is a limit value of electric power to be discharged from battery 400 (hereinafter, the “discharging power limit value” will be expressed as WOUT). The charging power value to battery 400 and the discharging power value from battery 400 are limited so as not to exceed these WIN and WOUT. It is to be noted that a maximum value of WOUT (a maximum value of discharging power) is W(MAX). Further, other well-known techniques may be used as a method of limiting charging power and discharging power of battery 400, and detailed description thereof will not be repeated here.

In the present embodiment, when high-rate discharging from battery 400 is continuously performed, internal resistance is increased, and a phenomenon in which an output voltage from battery 400 starts decreasing rapidly at certain timing may occur. If this phenomenon continues further, battery 400 may be deteriorated. Unevenness of ion concentration in an electrolyte caused by performing high-rate discharging continuously is considered as one of the causes of this deterioration. When deterioration due to high-rate discharging occurs, the output voltage does not recover even if the discharging current value is decreased or charging is performed thereafter. Therefore, it is necessary to suppress high-rate discharging before such deterioration occurs. On the other hand, if high-rate discharging is suppressed too much, motive power performance of the vehicle required by a driver cannot be fully exhibited.

To solve this problem, in the present embodiment, a battery deterioration evaluation value D is calculated in response to a change in unevenness of lithium ion concentration in the electrolyte in battery 400, and discharging power limit value WOUT is set based on the calculated battery deterioration evaluation value I), thereby suppressing degradation of the motive power performance of the vehicle and suppressing deterioration of battery 400 due to high-rate discharging.

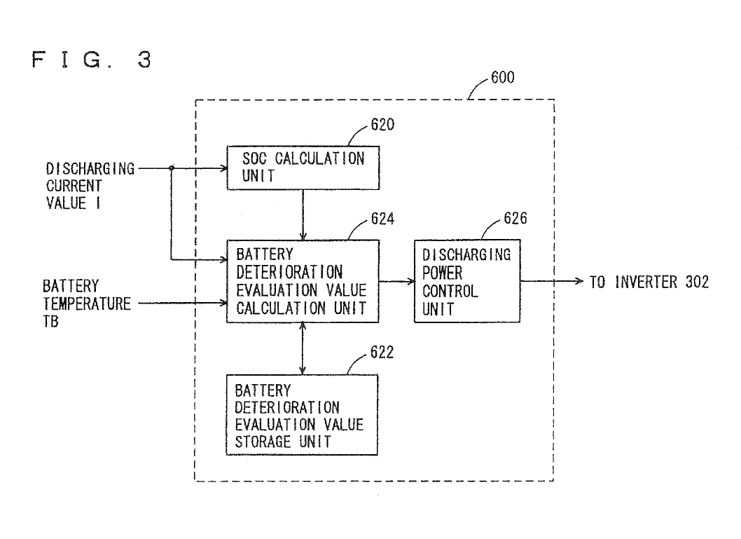

Referring to FIG. 3, a functional block diagram of the control apparatus in accordance with the present embodiment will be described. As shown in FIG. 3, the control apparatus includes an SOC calculation unit 620, a battery deterioration evaluation value storage unit 622, a battery deterioration evaluation value calculation unit 624, and a discharging power control unit 626.

SOC calculation unit 620 integrates the charging current values and the discharging current values detected by ammeter 612 to calculate the SOC of battery 400. In the following, description will be given assuming that ammeter 612 detects a discharging current value I, and that I has a positive value during discharging and has a negative value during charging.

Battery deterioration evaluation value storage unit 622 stores battery deterioration evaluation value D calculated by battery deterioration evaluation value calculation unit 624, in memory 604.

Battery deterioration evaluation value calculation unit 624 calculates battery deterioration evaluation value D based on discharging current value I from ammeter 612, battery temperature TB from battery temperature sensor 614, a value stored in memory 604 by battery deterioration evaluation value storage unit 622, a map stored in memory 604, and the like.

Discharging power control unit 626 sets discharging power limit value WOUT based on the calculated battery deterioration evaluation value D, and controls inverter 302 such that the discharging power value from battery 400 does not exceed set WOUT.

The control apparatus in accordance with the present embodiment having such functional blocks can be implemented either as hardware mainly configured by a digital circuit or an analog circuit, or as software mainly configured by CPU 602 and memory 604 included in ECU 600 and a program read from memory 604 and executed by CPU 602. It is said that, generally, if the control apparatus is implemented as hardware, it is advantageous in terms of an operation speed, and if the control apparatus is implemented as software, it is advantageous in terms of design change. Hereinafter, description will be given of a case where the control apparatus is implemented as software.

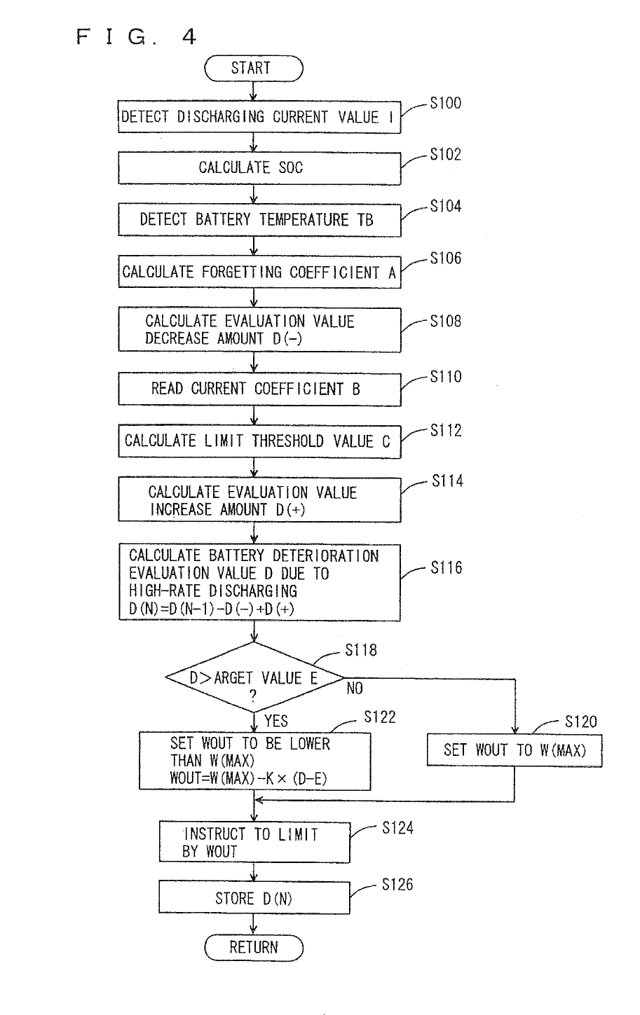

Referring to FIG. 4, a control structure of a program executed by ECU 600 serving as the control apparatus in accordance with the present embodiment will be described. It is to be noted that the program is repeatedly executed with a predetermined cycle time ΔT (for example, 0.1 seconds).

In step (hereafter abbreviated as S) 100, ECU 600 detects discharging current value I based on a signal from ammeter 612. As described above, during charging, discharging current value I is detected as a negative value.

In S102, ECU 600 calculates the SOC of battery 400 based on discharging current value I. In S104, ECU 600 detects battery temperature TB based on a signal from battery temperature sensor 614.

In S106, ECU 600 calculates a forgetting coefficient A based on the SOC of battery 400 and battery temperature TB. Forgetting coefficient A is a coefficient corresponding to a diffusion rate of lithium ions in the electrolyte in battery 400. Forgetting coefficient A is set such that a value of forgetting coefficient A×cycle time ΔT ranges from 0 to 1. For example, ECU 600 calculates forgetting coefficient A based on a map as shown in FIG. 5 using the SOC and battery temperature TB as parameters. In the map shown in FIG. 5, forgetting coefficient A is set to a high value when it is presumed that the diffusion rate of lithium ions is fast. Specifically, at the same battery temperature TB, forgetting coefficient A has a higher value with an increase in the SOC, and in the same SOC, forgetting coefficient A has a higher value with an increase in battery temperature TB.

In S108, ECU 600 calculates an evaluation value decrease amount D(−). Evaluation value decrease amount D(−) is calculated in response to a reduction of the unevenness of the lithium ion concentration caused by diffusion of lithium ions resulting from a lapse of one cycle time ΔT from the time of calculating a previous evaluation value. For example, ECU 600 calculates evaluation value decrease amount D(−), as forgetting coefficient A×cycle time ΔT×a previous value D(N−1). Here, previous value D(N−1) is a battery deterioration evaluation value calculated at a previous cycle time. D(0) (initial value) is, for example, 0. As described above, forgetting coefficient A×cycle time ΔT results in a value ranging from 0 to 1. As is clear from this calculation method, evaluation value decrease amount D(−) has a higher value with an increase in forgetting coefficient A (i.e., with an increase in the diffusion rate of lithium ions), and with an increase in cycle time ΔT. It is to be noted that a method of calculating evaluation value decrease. amount D(−) is not limited to this calculation method.

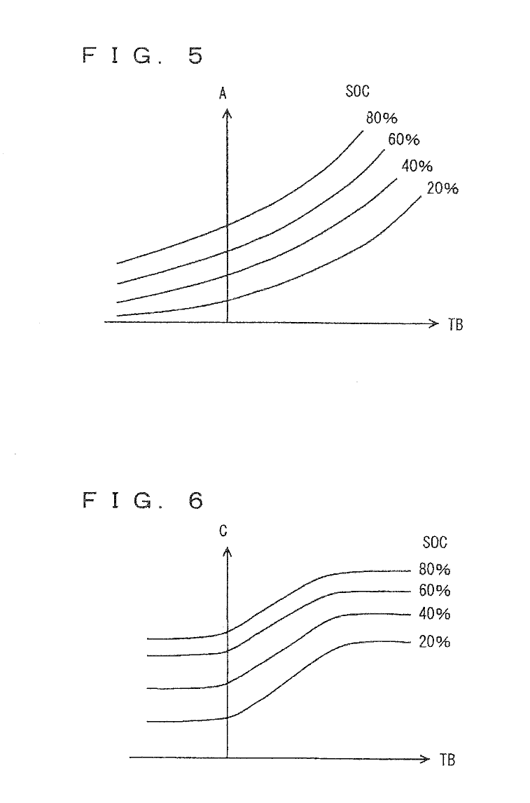

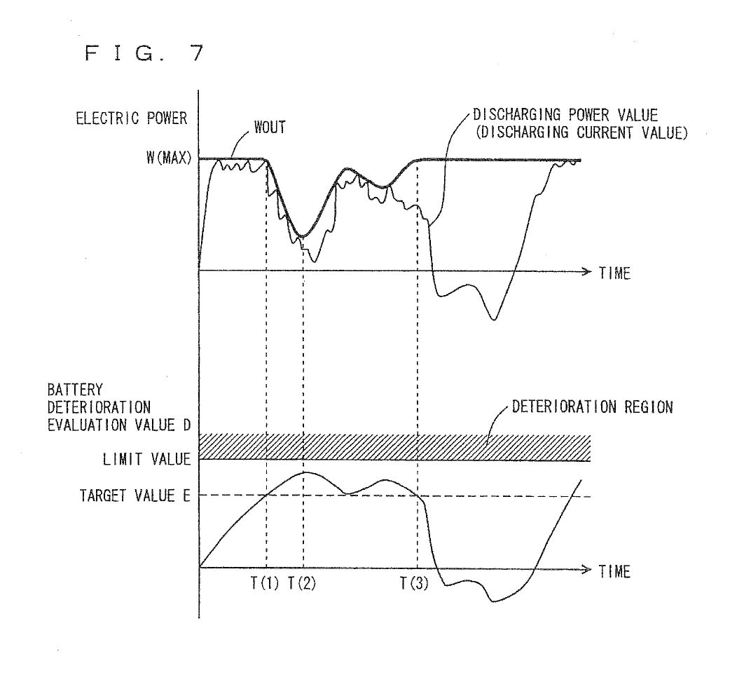

In S110, ECU 600 reads a current coefficient B stored in memory 604 beforehand. In S112, ECU 600 calculates a limit threshold value C based on the SOC of battery 400 and battery temperature TB. For example, ECU 600 calculates limit threshold value C based on a map as shown in FIG. 6 using the SOC and battery temperature TB as parameters. In the map shown in FIG. 6, at the same battery temperature TB, limit threshold value C becomes higher with an increase in the SOC, and in the same SOC, limit threshold value C becomes higher with an increase in battery temperature TB.

In S114, ECU 600 calculates an evaluation value increase amount D(+). Evaluation value increase amount D(+) is calculated in response to an increase of the unevenness of the lithium ion concentration caused by discharging during a lapse of one cycle time ΔT from the time of calculating a previous evaluation value. For example, ECU 600 calculates evaluation value increase amount D(+), as (current coefficient B/limit threshold value×discharging current value I×cycle time ΔT. As is clear from this calculation method, evaluation value increase amount D(+) has a higher value with an increase in discharging current value I, and with an increase in cycle time ΔT. It is to be noted that a method of calculating evaluation value increase amount D(+) is not limited to this calculation method.

In S116, ECU 600 calculates battery deterioration evaluation value D. If battery deterioration evaluation value D to be calculated at a present cycle time is defined as a present value D(N), ECU 600 calculates present value D(N), as previous value D(N−1)−evaluation value decrease amount D(−)+evaluation value increase amount D(+). As described above, D(0) (initial value) is, for example, 0.

In S118, ECU 600 determines whether or not battery deterioration evaluation value D exceeds a predetermined target value E. Target value E is set to a value lower than a deterioration region due to high-rate discharging. Target value E is set to a value such that battery deterioration evaluation value D does not reach the deterioration region even in a case where a decrease amount of WOUT per unit time is limited to an amount that does not impair drivability. If battery deterioration evaluation value D exceeds target value E (YES in S118), the process proceeds to S122. Otherwise (NO in S118), the process proceeds to S120.

In S120, ECU 600 sets WOUT to maximum value W(MAX). In 5122, ECU 600 sets WOUT to a value lower than maximum value W(MAX). ECU 600 sets WOUT as W(MAX)−a coefficient K×(battery deterioration evaluation value D−target value E), to decrease WOUT in response to a difference between battery deterioration evaluation value D and target value E. It is to be noted that a value of coefficient K is adjusted to limit the decrease amount of WOUT per unit time to an amount that does not impair drivability.

In S124, ECU 600 transmits to inverter 302 an instruction to limit the discharging power value of battery 400 by WOUT. In S126, ECU 600 stores present value D(N) (battery deterioration evaluation value D calculated at the present cycle time) in memory 604.

An operation of ECU 600 serving as the control apparatus in accordance with the present embodiment based on the structure and the flowchart as described above will be described.

Evaluation value decrease amount D(−) is calculated as forgetting coefficient A×x cycle time ΔT×previous value D(N−1) (S108). That is, evaluation value decrease amount D(−) has a higher value with an increase in forgetting, coefficient A indicating the diffusion rate of lithium ions, and with an increase in cycle time ΔT. Thereby, evaluation value decrease amount D(−) can be calculated to correspond to a reduction of the unevenness of the lithium ion concentration caused by diffusion of lithium ions resulting from a lapse of one cycle time ΔT from the time of calculating previous value D(N−1).

Evaluation value increase amount D(+) is calculated as (current coefficient B/limit threshold value C)×discharging current value I×cycle time ΔT (S114). That is, evaluation value increase amount D(+) has a higher value with an increase in discharging current value I, and with an increase in cycle time ΔT. Thereby, evaluation value increase amount D(+) can be calculated to correspond to an increase of the unevenness of the lithium ion concentration caused by discharging during a lapse of one cycle time ΔT from the time of calculating previous value D(N−1).

Present value D(N) of battery deterioration evaluation value D is calculated as previous value D(N−1)−evaluation value decrease amount D(−)+evaluation value increase amount D(+) (S116). Therefore, present value D(N) can be calculated taking both the increase of the unevenness of the lithium ion concentration caused by discharging and the reduction of the unevenness of the lithium ion concentration caused by diffusion of ions resulting from a lapse of time into consideration. Thereby, the increase and the reduction of the unevenness of the lithium ion concentration considered as a cause of deterioration due to high-rate discharging can be appropriately reflected in battery deterioration evaluation value D. Therefore, how close the state of battery 400 is to the state where deterioration due to high-rate discharging occurs can be properly recognized from battery deterioration evaluation value D.

Based on the evaluation value thus calculated, the value of the discharging power is controlled. Thereby, the discharging power can be limited at appropriate timing to achieve both suppression of deterioration due to discharging with a large current and motive power performance of the vehicle.

FIG. 7 is a timing chart of battery deterioration evaluation value D, WOUT, and the discharging power value of battery 400 limited by WOUT. As shown in FIG. 7, until time T(1) at which battery deterioration evaluation value D exceeds target value E, WOUT is set to W(MAX) (NO in S118; S120). When battery deterioration evaluation value D exceeds target value E at time T(1) (YES in S118), WOUT is decreased by the decrease amount per unit time represented as coefficient K×(battery deterioration evaluation value D−target value E) (S122, S124). On this occasion, by adjusting coefficient K, the decrease amount of WOUT per unit time is limited to an amount that does not impair drivability.

As WOUT is decreased, discharging current value I is decreased, and evaluation value increase amount D(+) also starts decreasing, and at time T(2), battery deterioration evaluation value D starts decreasing. Thereby, with the decrease amount of WOUT per unit time being limited to an amount that does not impair drivability, battery deterioration evaluation value D is decreased not to be included in the deterioration region, and thus deterioration of battery 900 due to high-rate discharging can be suppressed.

Thereafter, when battery deterioration evaluation value D falls below target value E at time T(3), WOUT is set to W(MAX) again (S120). Thereby, motive power performance of the vehicle required by the driver can be fully exhibited without unnecessarily limiting the discharging power of battery 400.

As has been described above, according to the control apparatus in accordance with the present embodiment, the battery deterioration evaluation value is calculated taking both the increase of the unevenness of the lithium ion concentration caused by discharging and the reduction of the unevenness of the lithium ion concentration caused by diffusion of ions resulting from a lapse of time into consideration. Thereby, the increase and the reduction of the unevenness of the lithium ion concentration can be appropriately reflected in the battery deterioration evaluation value. When the battery deterioration evaluation value thus calculated exceeds a target value, the discharging power from the battery is controlled. Thereby, the discharging power from the battery can be limited at appropriate timing to achieve both suppression of deterioration due to high-rate discharging and motive power performance of the vehicle.

In the present embodiment, battery deterioration evaluation value D calculated based on discharging current value I is stored at each cycle time, and present value D(N) is calculated using the stored previous value D(N−1). However, as long as battery deterioration evaluation value D is calculated based on a history of discharging current value I, the method of calculating battery deterioration evaluation value D is not necessarily limited to a method using previous value D(N−1). For example, battery deterioration evaluation value D may be calculated by calculating a value equivalent to previous value D(N−1) at each cycle time based on the history of discharging current value I.

It should be understood that the embodiment disclosed herein is illustrative and non-restrictive in every respect. The scope of the present invention is defined by the terms of the claims, rather than the description above, and is intended to include any modifications within the scope and meaning equivalent to the terms of the claims.

1. A control apparatus for a secondary battery mounted on a vehicle, comprising:
a detection unit detecting a charging current value to said secondary battery and a discharging current value from said secondary battery; and
a control unit connected to said detection unit,
said control unit storing a history of said charging current value and said discharging current value detected by said detection unit, presuming a change in unevenness of ion concentration in an electrolyte in said secondary battery based on said stored history, calculating an evaluation value related to deterioration of said secondary battery due to discharging to correspond to the change in said unevenness of the ion concentration, and controlling an upper limit value of discharging power from said secondary battery based on said calculated evaluation value,
said control unit shifting said evaluation value to a deterioration side when it is presumed that said unevenness of the ion concentration is increased, shifting said evaluation value to a non-deterioration side when it is presumed that said unevenness of the ion concentration is reduced, and setting said upper limit value of the discharging power when said evaluation value shifts to the deterioration side beyond a target value predetermined to be able to avoid the deterioration of said secondary battery due to discharging, to be lower than said upper limit value of the discharging power when said evaluation value does not shift to the deterioration side beyond said target value.

2. (canceled)

3. (canceled)

4. The control apparatus according to claim 1, wherein said control unit calculates a first amount for shifting said evaluation value to the deterioration side to be increased in response to an increase of said unevenness of the ion concentration due to discharging, calculates a second amount for shifting said evaluation value to the non-deterioration side to be increased in response to a reduction of said unevenness of the ion concentration due to a lapse of time, and calculates said evaluation value such that said evaluation value shifts to the deterioration side with an increase in said first amount and shifts to the non-deterioration side with an increase in said second amount.

5. The control apparatus according to claim 4, wherein said control unit presumes that said unevenness of the ion concentration is likely to be increased in a period from first timing to second timing at which a predetermined period has elapsed from said first timing, with an increase in said discharging current value detected at said second timing and with an increase in said predetermined period, and increases said first amount at said second timing with an increase in said discharging current value and with an increase in said predetermined period, presumes that said unevenness of the ion concentration is likely to be reduced in the period from said first timing to said second timing with an increase in said predetermined period, and increases said second amount at said second timing with an increase in said predetermined period, and calculates a value obtained by shifting said evaluation value at said first timing to the deterioration side by an amount corresponding to said first amount at said second timing and to the non-deterioration side by an amount corresponding to said second amount at said second timing, as said evaluation value at said second timing.

6. (canceled)

7. The control apparatus according to claim 1, wherein said control unit decreases said upper limit value of the discharging power with an increase in a difference between said evaluation value and said target value.

8. The control apparatus according to claim 1, wherein said secondary battery is a lithium ion battery.

9. A control apparatus for a secondary battery mounted on a vehicle, comprising:
means for detecting a charging current value to said secondary battery and a discharging current value from said secondary battery;
means for storing a history of said charging current value and said discharging current value;
calculation means for presuming a change in unevenness of ion concentration in an electrolyte in said secondary battery based on said history, and calculating an evaluation value related to deterioration of said secondary battery due to discharging to correspond to the change in said unevenness of the ion concentration; and
control means for controlling an upper limit value of discharging power from said secondary battery based on said evaluation value,
said calculation means shifting said evaluation value to a deterioration side when it is presumed that said unevenness of the ion concentration is increased, and shifting said evaluation value to a non-deterioration side when it is presumed that said unevenness of the ion concentration is reduced,
said control means setting said upper limit value of the discharging power when said evaluation value shifts to the deterioration side beyond a target value predetermined to be able to avoid the deterioration of said secondary battery due to discharging, to be lower than said upper limit value of the discharging power when said evaluation value does not shift to the deterioration side beyond said target value.

10. (canceled)

11. (canceled)

12. The control apparatus according to claim 9, wherein said calculation means includes
deterioration calculation means for calculating a first amount for shifting said evaluation value to the deterioration side to be increased in response to an increase of said unevenness of the ion concentration due to discharging,
non-deterioration calculation means for calculating a second amount for shifting said evaluation value to the non-deterioration side to be increased in response to a reduction of said unevenness of the ion concentration due to a lapse of time, and
evaluation value calculation means for calculating said evaluation value such that said evaluation value shifts to the deterioration side with an increase in said first amount and shifts to the non-deterioration side with an increase in said second amount.

13. The control apparatus according to claim 12, wherein
said deterioration calculation means presumes that said unevenness of the ion concentration is likely to be increased in a period from first timing to second timing at which a predetermined period has elapsed from said first timing with an increase in said discharging current value detected at said second timing and with an increase in said predetermined period, and increases said first amount at said second timing with an increase in said discharging current value and with an increase in said predetermined period,
said non-deterioration calculation means presumes that said unevenness of the ion concentration is likely to be reduced in the period from said first timing to said second timing with an increase in said predetermined period, and increases said second amount at said second timing with an increase in said predetermined period, and
said evaluation value calculation means includes means for calculating a value obtained by shifting said evaluation value at said first timing to the deterioration side by an amount corresponding to said first amount at said second timing and to the non-deterioration side by an amount corresponding to said second amount at said second timing, as said evaluation value at said second timing.

14. (canceled)

15. The control apparatus according to claim 9, wherein said control means includes means for decreasing said upper limit value of the discharging power with an increase in a difference between said evaluation value and said target value.

16. The control apparatus according to claim 9, wherein said secondary battery is a lithium ion battery.

17. A control method for a secondary battery mounted on a vehicle, comprising:
a step of detecting a charging current value to said secondary battery and a discharging current value from said secondary battery;
a step of storing a history of said charging current value and said discharging current value;
a calculation step of presuming a change in unevenness of ion concentration in an electrolyte in said secondary battery based on said history, and calculating an evaluation value related to deterioration of said secondary battery due to discharging to correspond to the change in said unevenness of the ion concentration; and
a control step of controlling an upper limit value of discharging power from said secondary battery based on said evaluation value,
said calculation step including a step of shifting said evaluation value to a deterioration side when it is presumed that said unevenness of the ion concentration is increased, and shifting said evaluation value to a non-deterioration side when it is presumed that said unevenness of the ion concentration is reduced,
said control step including a step of setting said upper limit value of the discharging power when said evaluation value shifts to the deterioration side beyond a target value predetermined to be able to avoid the deterioration of said secondary battery due to discharging to be lower than said upper limit value of the discharging power when said evaluation value does not shift to the deterioration side beyond said target value.

18. (canceled)

19. (canceled)

20. The control method according to claim 17, wherein said calculation step includes
deterioration calculation step of calculating a first amount for shifting said evaluation value to the deterioration side to be increased in response to an increase of said unevenness of the ion concentration due to discharging,
non-deterioration calculation step of calculating a second amount for shifting said evaluation value to the non-deterioration side to be increased in response to a reduction of said unevenness of the ion concentration due to a lapse of time, and
evaluation value calculation step of calculating said evaluation value such that said evaluation value shifts to the deterioration side with an increase in said first amount and shifts to the non-determination side with an increase in said second amount.

21. The control method according to claim 20, wherein
said deterioration calculation step includes a step of presuming that said unevenness of the ion concentration is likely to be increased in a period from first timing to second timing at which a predetermined period has elapsed from said first timing with an increase in said discharging current value detected at said second timing and with an increase in said predetermined period, and increasing said first amount at said second timing with an increase in said discharging current value and with an increase in said predetermined period,
said non-deterioration calculation step includes a step of presuming that said unevenness of the ion concentration is likely to be reduced in the period from said first timing to said second timing with an increase in said predetermined period, and increasing said second amount at said second timing with an increase in said predetermined period, and
said evaluation value calculation step includes a step of calculating a value obtained by shifting said evaluation value at said first timing to the deterioration side by an amount corresponding to said first amount at said second timing and to the non-deterioration side by an amount corresponding to said second amount at said second timing, as said evaluation value at said second timing.

22. (canceled)

23. The control method according to claim 17, wherein said control step includes a step of decreasing said upper limit value of the discharging power with an increase in a difference between said evaluation value and said target value.

24. The control method according to claim 17, wherein said secondary battery is a lithium ion battery.
